(19) United States
(12) Patent Application Publication
(10) Pub. No.: US 2014/0103517 A1
(43) Pub. Date: Apr. 17, 2014

(54) PACKAGE SUBSTRATE STRUCTURE AND SEMICONDUCTOR PACKAGE INCLUDING THE SAME

(71) Applicant: Samsung Electronics Co., Ltd., Suwon-Si (KR)

(72) Inventors: Sung-Kyu PARK, Hwaseong-si (KR); Hyeongmun KANG, Seoul (KR); Ji-Han KO, Hwaseong-si (KR)

(73) Assignee: SAMSUNG ELECTRONICS CO., LTD., Suwon-Si (KR)

(21) Appl. No.: 14/052,980

(22) Filed: Oct. 14, 2013

(30) Foreign Application Priority Data
Oct. 15, 2012 (JP) 10-2012-0114300

(51) Int. Cl. H01L 23/50

(52) U.S. Cl. CPC H01L 23/50
USPC 257/685

(57) ABSTRACT

A package substrate includes a substrate including a top surface and a bottom surface facing each other, the top surface including a first region where a semiconductor chip is mounted and a second region surrounding the first region, and a dummy post on the second region of the top surface to protrude upward from the top surface.

### CROSS-REFERENCE TO RELATED APPLICATIONS

This U.S. non-provisional patent application claims priority under 35 U.S.C. §119 to Korean Patent Application No. 10-2012-0114300, filed on October 15, 2012, in the Korean Intellectual Property Office, the entire contents of which are hereby incorporated by reference.

### BACKGROUND

1. Field

Some example embodiments of the inventive concepts relate to a semiconductor device, and in particular, to a package substrate structure and a semiconductor package including the same.

2. Description of the Related Art

Recently in the electronic industry, small and slim printed circuit boards (PCBs) have been increasingly demanded with the development of thinner, lighter, smaller, slimmer and higher packing density of electronic products. That is, a substrate for PCB (hereinafter, referred as to a package substrate) becomes thinner and a package product becomes slimmer. However, this may lead to warpage of a semiconductor package, because of a difference in thermal expansion coefficient between a semiconductor chip, an epoxy molding compound, and a package substrate. The warpage of the semiconductor package may result in technical problems, such as a vacuum error or a delivery failure, in a packaging process.

### SUMMARY

Some example embodiments of the inventive concepts provide a structure, a package substrate structure and a semiconductor package with improved characteristics of warpage and reliability.

According to an example embodiment of the inventive concepts, a semiconductor package includes a package substrate with a first region and a second region surrounding the first region, a semiconductor chip on the first region, at least one dummy post on the second region and spaced apart from the semiconductor chip, and a mold layer covering the semiconductor chip.

In an example embodiment, the second region of the package substrate may include an edge, and the at least one dummy post may be adjacent to the edge of the second region.

In an example embodiment, the edge may be a plurality of edges, and the at least one dummy post may be adjacent to a corner of the package substrate that may be an intersection of the plurality of edges.

In an example embodiment, the at least one dummy post may be in contact with the edge and protrudes upward from the package substrate.

In an example embodiment, the at least one dummy post may have at least one of a hexahedral shape, a cylindrical shape, and a polyhedral shape.

In an example embodiment, the at least one dummy post may include a plurality of dummy posts arranged adjacent to each other to form at least one dummy post group.

In an example embodiment, the at least one dummy post may include a solder resist material.

In an example embodiment, the mold layer may include an epoxy molding compound, and the package substrate may have a thermal expansion coefficient different from the mold layer.

According to another example embodiment of the inventive concepts, a package substrate includes a substrate including a top surface and a bottom surface facing each other, the top surface including a first region where a semiconductor chip may be mounted and a second region surrounding the first region, and at least one dummy post on the second region of the top surface to protrude upward from the top surface.

In another example embodiment, the second region of the substrate may include an edge, and the at least one dummy post may be in contact with the edge.

In another example embodiment, the second region of the substrate may include an edge, and the at least one dummy post may be spaced apart from the edge.

In another example embodiment, the at least one dummy post may have at least one of a hexahedral shape, a cylindrical shape, and a polyhedral shape.

In another example embodiment, the at least one dummy post may include a plurality of dummy posts arranged adjacent to each other to form at least one dummy post group.

In another example embodiment, the at least one dummy post may include a solder resist material.

According to yet another example embodiment, a structure includes at least one dummy post adjacent to an edge of a substrate and protruding upward from a surface of the substrate, and a mold layer covering the surface of the substrate including the at least one dummy post.

In yet another example embodiment, the structure may further include a semiconductor chip on the surface of the substrate, and the semiconductor chip may be spaced apart from the at least one dummy post.

In yet another example embodiment, the at least one dummy post may have at least one of a hexahedral shape, a cylindrical shape, and a polyhedral shape.

In yet another example embodiment, the at least one dummy post may include a plurality of dummy posts arranged adjacent to each other to form at least one dummy post group.

In yet another example embodiment, the at least one dummy post may include a solder resist material.

In yet another example embodiment, the mold layer may include an epoxy molding compound, and the substrate has a thermal expansion coefficient different from the mold layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a plan view illustrating an example of package substrates according to an example embodiment of the inventive concepts.

FIG. 1B is a sectional view taken along line A-B of FIG. 1A.

FIG. 2A is a plan view illustrating an example of package substrates according to another example embodiment of the inventive concepts.

FIG. 2B is a sectional view taken along line A-B of FIG. 2A.

FIG. 3A is a plan view illustrating an example of package substrates according to still another example embodiment of the inventive concepts.

FIG. 3B is a sectional view taken along line A-B of FIG. 3A.

FIG. 4A is a plan view illustrating an example of package substrates according to even another example embodiment of the inventive concepts.

FIG. 4B is a sectional view taken along line A-B of FIG. 4A.

FIG. 5 is a sectional view illustrating a package substrate according to an example embodiment of the inventive concepts.

FIGS. 6 through 8 are sectional views illustrating a method of fabricating a semiconductor package according to an example embodiment of the inventive concepts.

FIG. 9 is a diagram illustrating an example of package modules including semiconductor packages according to an example embodiment of the inventive concepts.

FIG. 10 is a schematic block diagram illustrating an example of electronic systems including semiconductor packages according to an example embodiment of the inventive concepts.

FIG. 11 is a schematic block diagram illustrating an example of memory systems including semiconductor packages according to an example embodiment of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

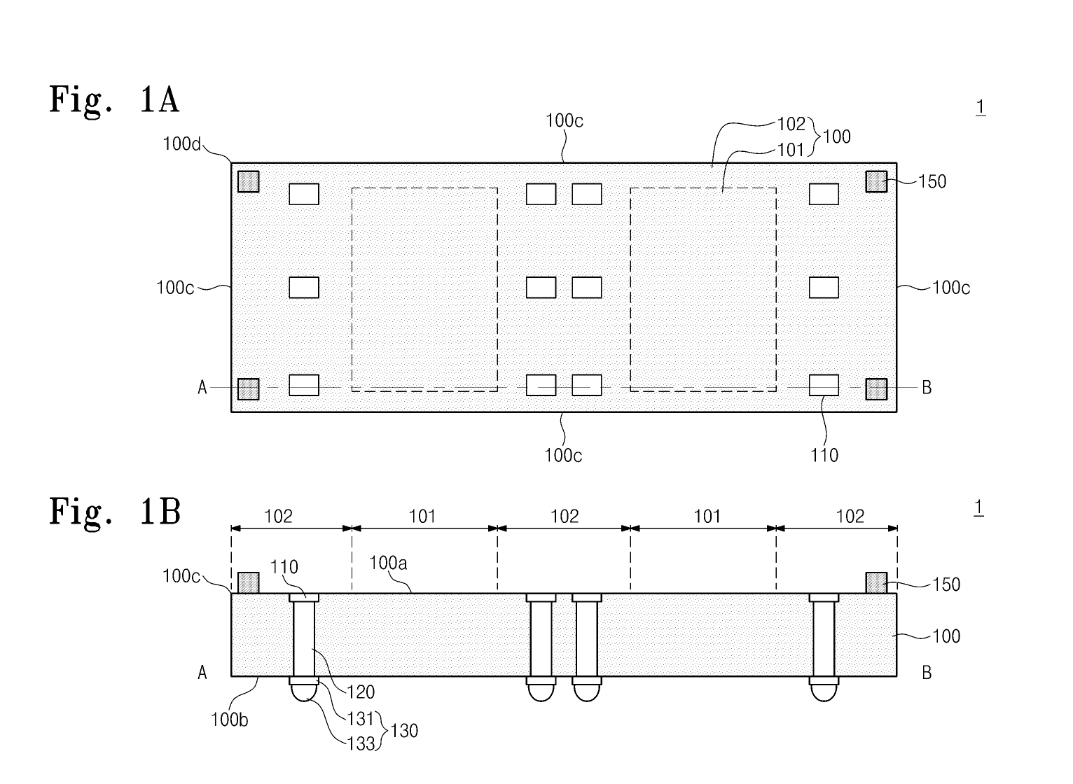

FIG. 1A is a plan view illustrating an example of package substrates according to an example embodiment of the inventive concepts. FIG. 1B is a sectional view taken along line A-B of FIG. 1A.

Referring to FIGS. 1A and 1B, a package substrate 1 may include a substrate 100 and a dummy post 150 on the substrate 100.

The substrate 100 may be a printed circuit board (PCB) with patterns. The substrate 100 may include a first region 101 where a semiconductor chip will be mounted and a second region 102 around the first region 101. The substrate 100 may include a top surface 100a and a bottom surface 100b facing each other. The second region 102 may include edges 100c corresponding to edges of the substrate 100 and at least one corner 100d provided at an intersection of the edges 100c. The substrate 100 may include an inner pad 110, a through via 120, and/or an outer connection terminal 130. The through via 120 may connect the inner pad 110 on the top surface 100a of the substrate 100 electrically with the outer connection terminal 130 on the bottom surface 100b of the substrate 100. The outer connection terminal 130 may include a pad 131 and/or a solder ball 133 on the pad 131. The substrate 100 may include an epoxy-based material and/or a ceramic material.

The dummy post 150 may be provided on the second region 102 of the substrate 100 and be spaced apart from the first region 101. The dummy post 150 may be provided on the top surface 100a of the substrate 100 and adjacent to the corner 100d of the second region 102. The dummy post 150 may have a structure protruding upward from the substrate 100. For example, the dummy post 150 may have one of various shapes, such as a hexahedral shape, a cylindrical shape, or a polyhedral shape. The dummy post 150 may include a solder resist material. In an example embodiment, the dummy post 150 may be electrically isolated from conductive components of the package substrate 1.

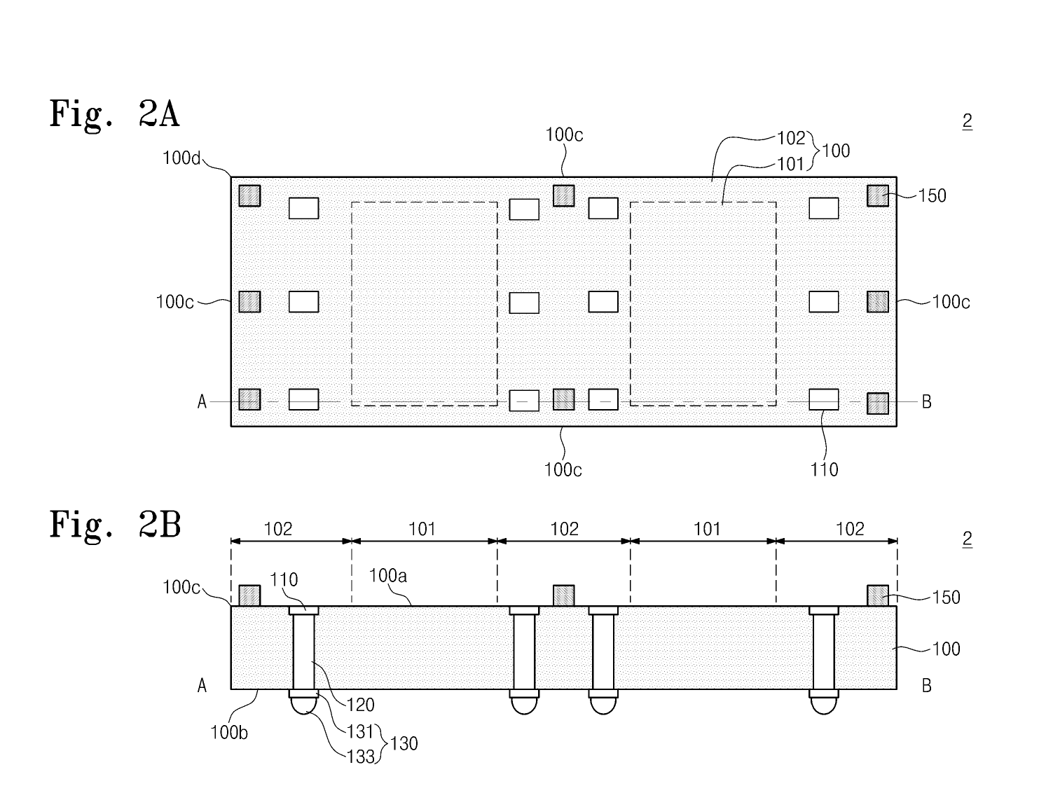

FIG. 2A is a plan view illustrating an example of package substrates according to another example embodiment of the inventive concepts. FIG. 2B is a sectional view taken along line A-B of FIG. 2A. For the sake of brevity, the elements and features of this example that are similar to those previously shown and described will not be described in much further detail.

Referring to FIGS. 2A and 2B, a package substrate 2 may include a substrate 100 and the dummy post 150 on the substrate 100.

The substrate 100 may include the first region 101 where a semiconductor chip will be mounted and the second region 102 around the first region 101. The second region 102 may include the edges 100c and at least one corner 100d provided at an intersection of the edges 100c.

The dummy post 150 may be provided on the second region 102 of the substrate 100 and spaced apart from the first region 101. In an example embodiment, the dummy post 150 may be provided adjacent to the corner 100d of the substrate 100. In another example embodiment, the dummy post 150 may be provided between an adjacent pair of the corners 100d of the second region 102 and adjacent to the edge 100c of the second region 102. The dummy post 150 may protrude upward from the substrate 100.

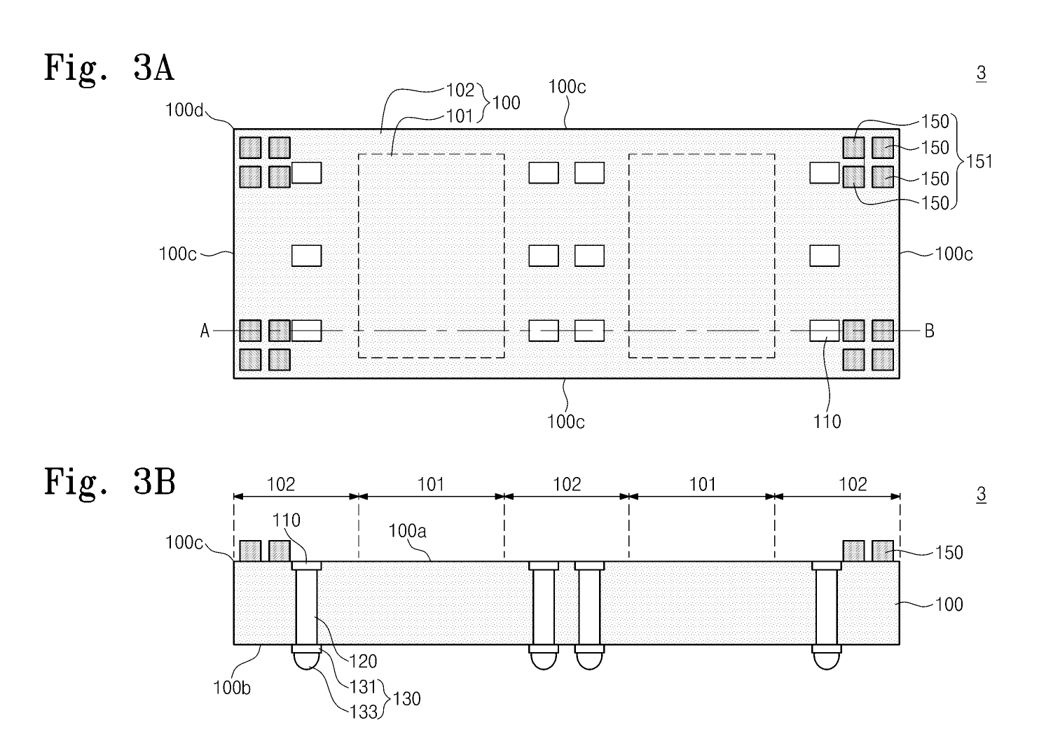

FIG. 3A is a plan view illustrating an example of package substrates according to still another example embodiment of the inventive concepts. FIG. 3B is a sectional view taken along line A-B of FIG. 3A. For the sake of brevity, the elements and features of this example that are similar to those previously shown and described will not be described in much further detail.

Referring to FIGS. 3A and 3B, a package substrate 3 may include the substrate 100 and the dummy post 150 on the substrate 100. The substrate 100 may include the first region 101 where a semiconductor chip will be mounted and the second region 102 around the first region 101.

A dummy post group 151 may be provided on the second region 102 of the substrate 100 and adjacent to the corner 100d. The dummy post group 151 may include a plurality of dummy posts 150 that are provided adjacent to each other. The dummy post 150 may have a structure protruding upward from the package substrate 100. For example, the dummy post 150 may have one of various shapes, such as a hexahedral shape, a cylindrical shape, or a polyhedral shape.

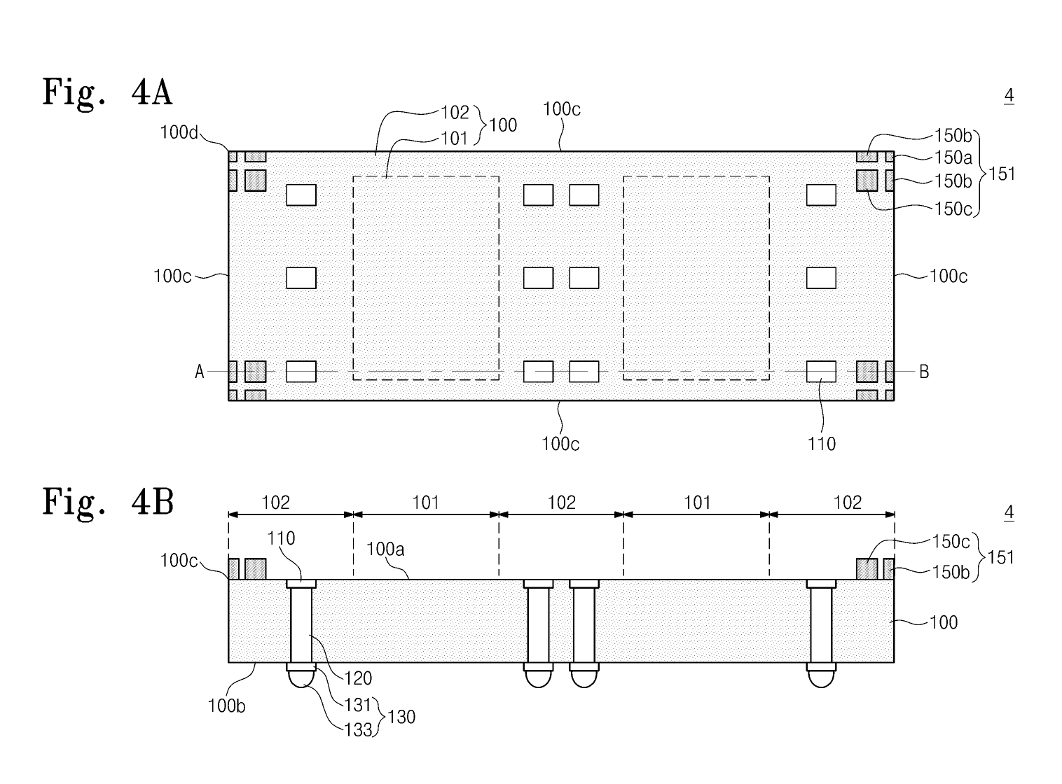

FIG. 4A is a plan view illustrating an example of package substrates according to even another example embodiment of the inventive concepts. FIG. 4B is a sectional view taken along line A-B of FIG. 4A.

Referring to FIGS. 4A and 4B, a package substrate 4 may include the substrate 100, a first dummy post 150a, a second dummy post 150b, and a third dummy post 150c.

The substrate 100 may include the first region 101 and the second region 102. The first region 101 may be a region where a semiconductor chip 200 will be mounted. The second region 102 may be provided around the first region 101.

The dummy post group 151 may be provided on the second region 102 of the substrate 100 and adjacent to the corner 100d. The dummy post group 151 may include the first dummy post 150a, the second dummy post 150b, and the third dummy post 150c that are arranged adjacent to each other. The first dummy post 150a may be in contact with the corner 100d. The second dummy post 150b may be provided spaced apart from and adjacent to the corner 100d. The first and second dummy posts 150a and 150b may be in contact with the edge 100c and extend on the top surface 100a of the substrate 100. The third dummy post 150c may be provided adjacent to the corner 100d of the second region 102 and spaced apart from the edge 100c.

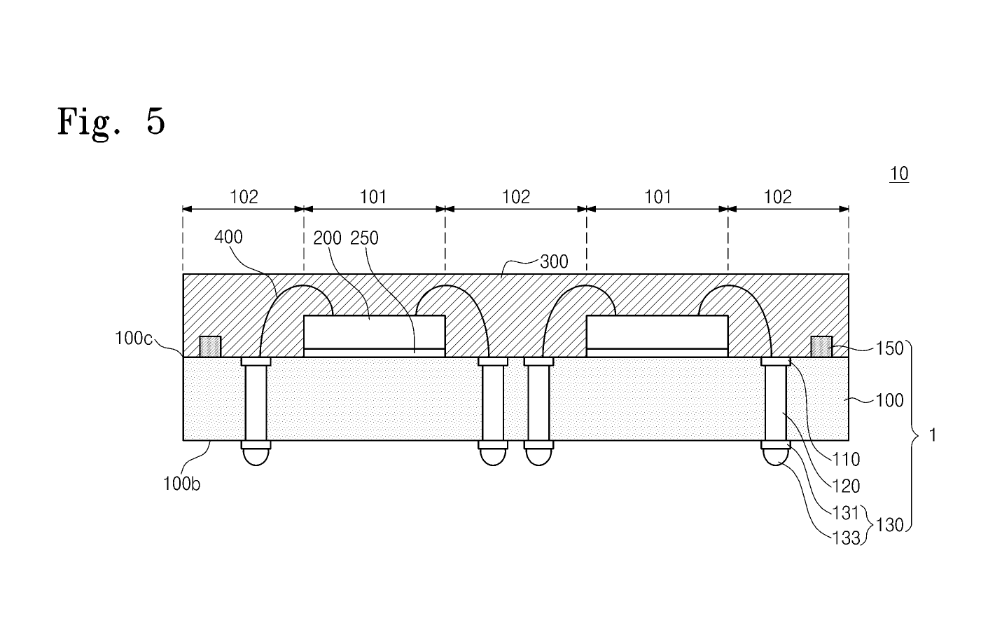

Hereinafter, the semiconductor package according to an example embodiment of the inventive concepts will be described with reference to FIG. 5. FIG. 5 is a sectional view illustrating a package substrate according to an example embodiment of the inventive concepts.

Referring to FIG. 5, a semiconductor package 10 may include the package substrate 1, the semiconductor chip 200, and a mold layer 300. The dummy post 150 may be provided on the package substrate.

The package substrate 1 may be configured to have the same features as those described with reference to FIGS. 1A and 1B. The dummy post 150 may be spaced apart from the semiconductor chip 200. For the sake of brevity, the elements and features of this example that are similar to those previously shown and described with reference to FIGS. 1A and 1B will not be described in much further detail.

The semiconductor chip 200 may be mounted on the first region 101 of the substrate 100. For example, the semiconductor chip 200 may be mounted on the substrate 100 with a bonding wire connecting them. An attachment film 250 may be provided between the semiconductor chip 200 and the substrate 100 to attach the semiconductor chip 200 to the substrate 100. The semiconductor chip 200 may be electrically connected to the substrate 100 and an external electronic device via a bonding wire 400. The bonding wire 400 may include a conductive material (e.g., gold (Au), aluminum (Al), copper (Cu) and/or alloys thereof).

The mold layer 300 may be provided around the semiconductor chip 200 to encapsulate the semiconductor package 10. The mold layer 300 may be configured to protect the substrate 100 and/or the semiconductor chip 200 against external chemical or physical attacks. The mold layer 300 may be in contact with at least a portion of the top surface 100a of the substrate 100. The mold layer 300 may include a material whose thermal expansion coefficient is different from that of the substrate 100. The mold layer 300 may include a resin (e.g., epoxy molding compound (EMC) material).

Since the substrate 100 includes a material whose thermal expansion coefficient is different from that of the mold layer 300, a warpage of the semiconductor package 10 may occur. In general, the warpage of the semiconductor package 10 may occur near the edge portion of the semiconductor package 10. The dummy post 150 may be provided at positions where the warpage of the semiconductor package 10 may occur. Due to the presence of the dummy post 150, reducing a contact area between the substrate 100 and the mold layer 300 near the dummy post 150 may be possible. Further, around the dummy post 150, a ratio in volume of the mold layer 300 to the semiconductor package 10 can be reduced. Accordingly, improving the warpage of the semiconductor package 10 may be possible. The dummy post 150 may be used to join the substrate 100 to the mold layer 300, and thus, preventing or inhibiting delamination between the substrate 100 and the mold layer 300 may be possible.

Table 1 shows warpage properties of semiconductor packages according to experimental examples of the inventive concepts. A comparative example represents a warpage evaluation result on a semiconductor package in which the dummy post 150 is not provided. Experimental example 1 represents a warpage evaluation result on a semiconductor package, in which the package substrate 3 described with reference to FIGS. 3A and 3B is provided. Experimental example 2 represents a warpage evaluation result on a semiconductor package, in which the package substrate 4 described with reference to FIGS. 4A and 4B is provided. The warpage evaluation of the semiconductor package was conducted under coplanarity criteria of 80 μm and 100 μm, respectively, for Evaluation Specifications 1 and 2.

TABLE 1

| | Evaluation Spec. 1 | | | Evaluation Spec. 2 | | |
|---|---|---|---|---|---|---|
| | | Desir- | | | Desir- | |
| | The total | able | | The total | able | |
| | number of | result | Yield | number of | result | Yield |
| | experiments | (#) | (%) | experiments | (#) | (%) |
| Compar- | 457 | 74 | 16.2 | 457 | 209 | 45.7 |
| ative | | | | | | |
| example | | | | | | |
| Experi- | 157 | 80 | 51.0 | 157 | 157 | 100.0 |
| mental | | | | | | |
| example 1 | | | | | | |
| Experi- | 202 | 95 | 47.0 | 202 | 202 | 100.0 |
| mental | | | | | | |
| example 2 | | | | | | |

As shown in Table 1, semiconductor packages had an improved warpage property when the dummy posts 150 were provided in semiconductor packages.

[Methods]

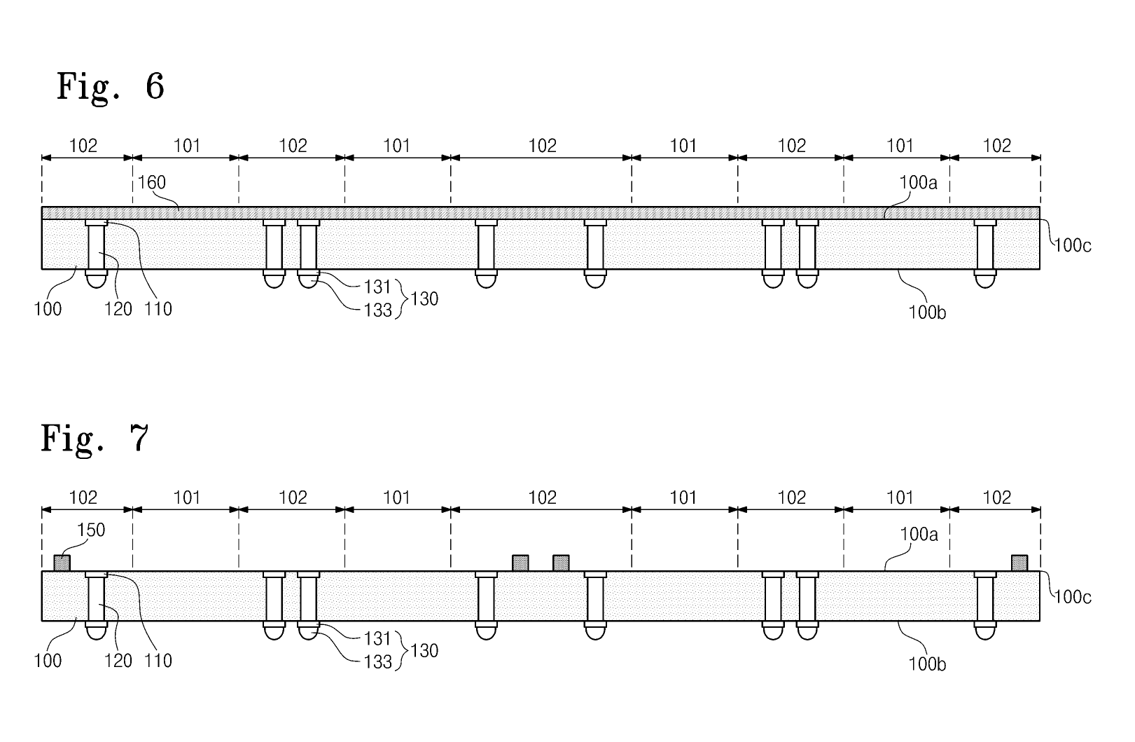

FIGS. 6 through 8 are sectional views illustrating a method of fabricating a semiconductor package according to an example embodiment of the inventive concepts. For the sake of brevity, the elements and features of this example that are similar to those previously shown and described will not be described in much further detail.

Referring to FIG. 6, a solder resist layer 160 may be formed on a substrate 100. The substrate 100 may include a first region 101 and a second region 102. The substrate 100 may include a top surface 100a and a bottom surface 100b facing each other and a side surface 100c connecting the top surface 100a to the bottom surface 100b. As described with reference to FIGS. 1A through 4B, the second region 102 may include edges 100c and at least one corner 100d provided at an intersection of the edges 100c. An inner pad 110, a through via 120, and/or an outer connection terminal 130 may be provided on or in the substrate 100. The solder resist layer 160 may be formed by a lamination process including a step of depositing a dry film.

Referring to FIG. 7, a dummy post 150 may be formed by patterning the solder resist layer 160. In an example embodiment, the patterning of the solder resist layer 160 may be performed using a photolithography process.

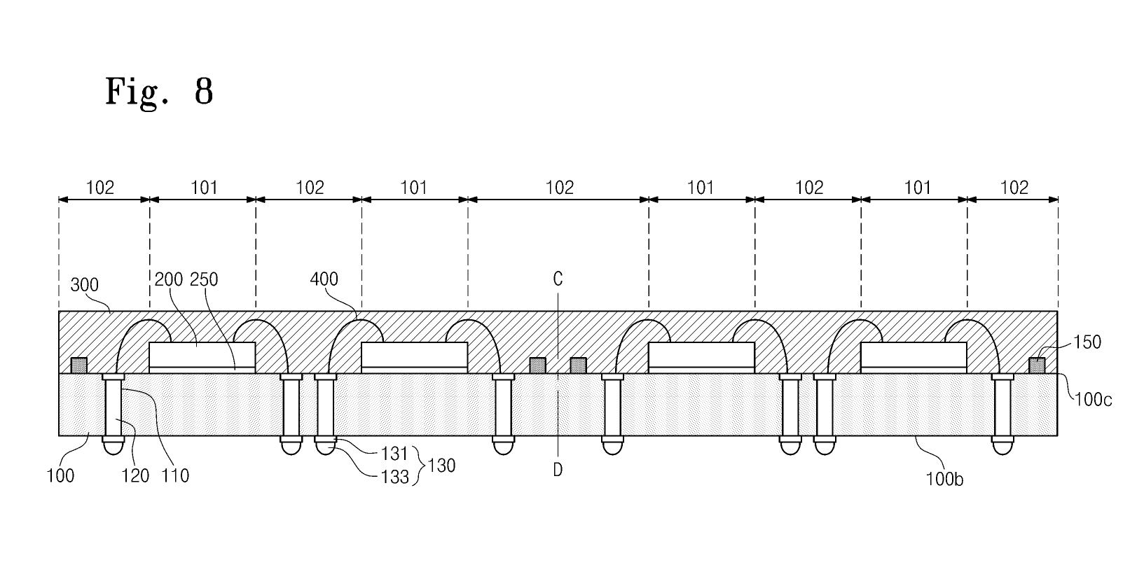

Referring to FIG. 8, a semiconductor chip 200 may be mounted on the first region 101 of the substrate 100, and a mold layer 300 may be formed on the resulting structure. An attachment film 250 and the semiconductor chip 200 may be sequentially provided on the first region 101. By using the attachment film 250, the semiconductor chip 200 may be attached to the substrate 100. The semiconductor chip 200 may be mounted in such a way that the semiconductor chip 200 is provided spaced apart from the dummy post 150. A bonding wire 400 may be formed to connect the semiconductor chip 200 to the inner pad 110 of the substrate 100. The mold layer 300 may be formed to cover or encapsulate the substrate 100 and/or the semiconductor chip 200, and may be formed of, for example, an EMC material. Thereafter, the resulting structure may be cut along, for example, line C-D of FIG. 8, by a singulation process. As the result of the singulation process, the semiconductor package 10 may be formed as shown in FIG. 5.

[Applications]

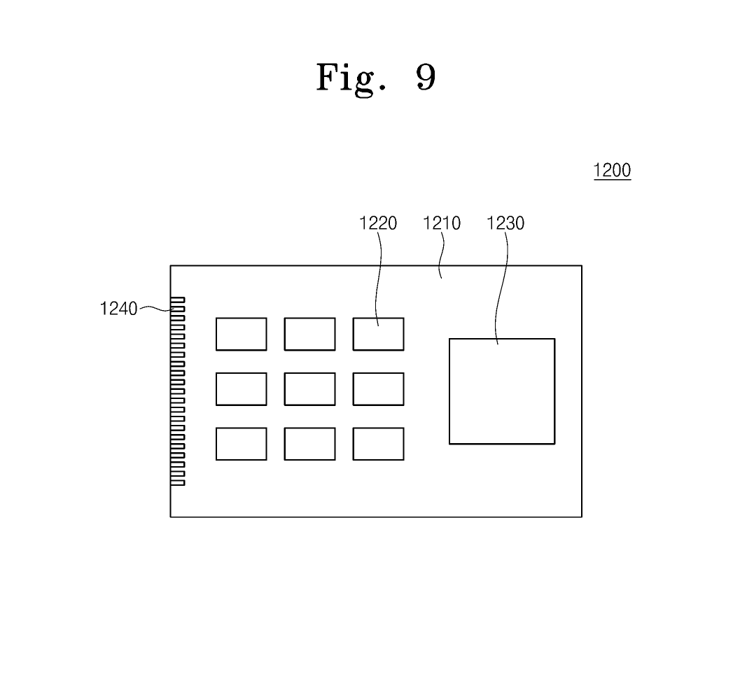

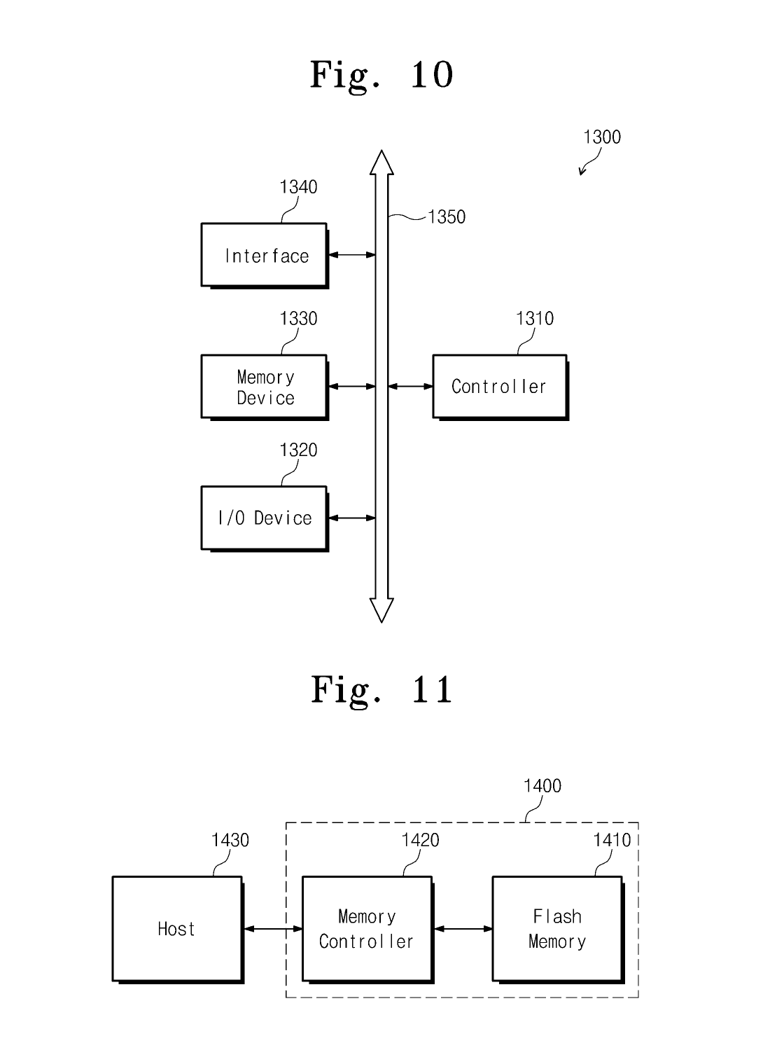

FIG. 9 is a diagram illustrating an example of package modules including semiconductor packages according to various example embodiments of the inventive concepts. FIG. 10 is a schematic block diagram illustrating an example of electronic systems including semiconductor packages according to various example embodiments of the inventive concepts. FIG. 11 is a schematic block diagram illustrating an example of memory systems including semiconductor packages according to various example embodiments of the inventive concepts.

Referring to FIG. 9, a package module 1200 may include semiconductor devices 1220 and a semiconductor device 1230 packaged in a quad flat package (QFP) type. The semiconductor devices 1220 and 1230 may include the semiconductor package 10 according to various example embodiments of the inventive concepts. The package module 1200 may be connected to an external electronic device through an external connection terminal 1240 disposed at one side of the package substrate 1210.

Referring to FIG. 10, an electronic system 1300 may include a controller 1310, an input/output (1/0) unit 1320, and a memory device 1330. The controller 1310, the I/O unit 1320 and the memory device 1330 may be combined with each other through a data bus 1350. The data bus 1350 may correspond to a path through which electrical signals are transmitted. The controller 1310 may include at least one of a microprocessor, a digital signal processor, a microcontroller or another logic device. The other logic device may have a similar function to any one of the microprocessor, the digital signal processor and the microcontroller. The controller 1310 and the memory device 1330 may include the semiconductor package 10 according to various example embodiments of the inventive concepts. The I/O unit 1320 may include a keypad, a keyboard and/or a display unit. The memory device 1330 may store data and/or commands executed by the controller 1310. The memory device 1330 may include a volatile memory device and/or a non-volatile memory device. For example, the memory device 1330 may include a FLASH memory device. The flash memory device may be realized as solid state disks (SSD). In this case, the electronic system 1300 may stably store mass data to the flash memory system. The electronic system 1300 may further include an interface unit 1340 which transmits electrical data to a communication network or receives electrical data from a communication network. The interface unit 1340 may operate by wireless or cable. For example, the interface unit 1340 may include an antenna for wireless communication or a transceiver for cable communication. Although not shown in the drawings, an application chipset and/or a camera image processor (CIS) may further be provided in the electronic system 1300.

The electronic system 1300 may be realized as a mobile system, a personal computer, an industrial computer, or a logic system performing various functions. For example, the mobile system may be one of a personal digital assistant (PDA), a portable computer, a web tablet, a wireless phone, a mobile phone, a laptop computer, a digital music system, and an information transmit/receive system. When the electronic system 1300 performs wireless communication, the electronic system 1300 may be used in a communication interface protocol of a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, and so forth.

Referring to FIG. 11, a memory system 1400 may include a non-volatile memory device 1410 and a memory controller 1420. The non-volatile memory device 1410 and the memory controller 1420 may store data or read stored data. The non-volatile memory device 1410 may include the semiconductor package 10 according to various example embodiments of the inventive concepts. The memory controller 1420 may control the non-volatile memory device 1410 in order to read the stored data and/or to store data in response to read/write request of a host 1430.

According to example embodiments of the inventive concepts, a package substrate may include a first region where a semiconductor chip will be mounted and a second region surrounding the first region. At least one dummy post may be provided on the second region to protrude upward from the package substrate. In general, warpage of a semiconductor package may occur near an edge portion of the semiconductor package. The dummy post may be provided at positions where the warpage of the semiconductor package may occur, and thus, it is possible to suppress the warpage of the semiconductor package. In addition, the dummy post may be used to join the package substrate to a mold layer, and thus, it is possible to prevent or inhibit delamination between the package substrate and the mold layer.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor package comprising:
a package substrate with a first region and a second region surrounding the first region;
a semiconductor chip on the first region;
at least one dummy post on the second region, the at least one dummy post spaced apart from the semiconductor chip; and
a mold layer covering the semiconductor chip.

2. The semiconductor package of claim 1, wherein
the second region of the package substrate includes an edge, and
the at least one dummy post is adjacent to the edge of the second region.

3. The semiconductor package of claim 2, wherein
the edge is a plurality of edges, and
the at least one dummy post is adjacent to a corner of the package substrate, the corner being an intersection of the plurality of edges.

4. The semiconductor package of claim 2, wherein the at least one dummy post is in contact with the edge and protrudes upward from the package substrate.

5. The semiconductor package of claim 1, wherein the at least one dummy post has at least one of a hexahedral shape, a cylindrical shape, and a polyhedral shape.

6. The semiconductor package of claim 1, wherein the at least one dummy post includes a plurality of dummy posts arranged adjacent to each other to form at least one dummy post group.

7. The semiconductor package of claim 1, wherein the at least one dummy post includes a solder resist material.

8. The semiconductor package of claim 1, wherein the mold layer includes an epoxy molding compound, and the package substrate has a thermal expansion coefficient different from the mold layer.

9. A package substrate structure comprising:
a substrate including a top surface and a bottom surface facing each other, the top surface including a first region where a semiconductor chip is mounted and a second region surrounding the first region; and
at least one dummy post on the second region of the top surface to protrude upward from the top surface.

10. The package substrate structure of claim 9, wherein
the second region of the substrate includes an edge, and
the at least one dummy post is in contact with the edge.

11. The package substrate structure of claim 9, wherein
the second region of the substrate includes an edge, and
the at least one dummy post is spaced apart from the edge.

12. The package substrate structure of claim 9, wherein the at least one dummy post has at least one of a hexahedral shape, a cylindrical shape, and a polyhedral shape.

13. The package substrate structure of claim 9, wherein the at least one dummy post includes a plurality of dummy posts arranged adjacent to each other to form at least one dummy post group.

14. The package substrate structure of claim 9, wherein the at least one dummy post includes a solder resist material.

15. A structure comprising:
at least one dummy post adjacent to an edge of a substrate and protruding upward from a surface of the substrate; and
a mold layer covering the surface of the substrate including the at least one dummy post.

16. The structure of claim 15, further comprising:
a semiconductor chip on the surface of the substrate, the semiconductor chip spaced apart from the at least one dummy post.

17. The semiconductor package of claim 15, wherein the at least one dummy post has at least one of a hexahedral shape, a cylindrical shape, and a polyhedral shape.

18. The semiconductor package of claim 15, wherein the at least one dummy post includes a plurality of dummy posts arranged adjacent to each other to form at least one dummy post group.

19. The semiconductor package of claim 15, wherein the at least one dummy post includes a solder resist material.

20. The semiconductor package of claim 15, wherein the mold layer includes an epoxy molding compound, and the substrate has a thermal expansion coefficient different from the mold layer.
